(19) United States
(12) Patent Application Publication
(10) Pub. No.: US 2006/0202288 A1
(43) Pub. Date: Sep. 14, 2006

(54) Insulator composition, organic semiconductor device, electronic device, and electronic apparatus

(75) Inventors: Hitoshi Yamamoto, Chino-shi (JP); Soichi Moriya, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/360,804

(22) Filed: Feb. 24, 2006

(30) Foreign Application Priority Data
Mar. 11, 2005 (JP) 2005-070074

(51) Int. Cl. H01L 29/94

(52) U.S. Cl. 257/410; 257/411; 257/E29.117

(57) ABSTRACT

An insulator composition includes a polysilsesquioxane derivative with an organic group as a substituent, the insulator composition being used for formation of an insulating section that an organic semiconductor device includes.

### BACKGROUND OF THE INVENTION

1. Technical Field

The present invention relates to an insulator composition, an organic semiconductor device, an electronic device, and an electronic apparatus.

2. Related Art

In recent years, it has been promoted to develop thin film transistors (TFTs) using organic materials (organic semiconductor materials) that exhibit semiconducting conductivity.

These TFTs have advantages such as suitability for thickness and weight reduction, flexibility, and low material cost, and therefore are expected to be used as switching elements for flexible displays and the like.

Among the TFTs as described above, there is a TFT using an inorganic material as the material for its gate insulating layer. For reference, see JP-A-2000-103719, which is an example of related art.

If a gate insulating layer is made by using an inorganic material, the gate insulating layer prevents the invasion of moisture into an organic semiconductor layer to some extent since the inorganic material has hygroscopicity. Hence, the characteristics of the TFT can be restrained from deteriorating over time.

However, this gate insulating layer requires a vapor phase film formation method to be used for its formation, and therefore involves problems. Its formation by using the method takes time and trouble. Furthermore, the method may cause the deterioration or degradation of the organic semiconductor layer during the formation of the gate insulating layer.

### SUMMARY

An advantage of the invention is to provide an insulator composition capable of easily forming an insulating section with high hygroscopicity, and an organic semiconductor device, an electronic device, and an electronic apparatus that have high reliability.

Such an advantage can be achieved according to aspects of the invention as described below.

An insulator composition according to a first aspect of the invention includes a polysilsesquioxane derivative with an organic group as a substituent, and is used for the formation of an insulating section that an organic semiconductor device includes.

Thus, the insulating section with high hygroscopicity can easily be formed.

In the insulator composition according to the first aspect of the invention, the polysilsesquioxane derivative is preferably at least one kind of compounds represented by formulas (1) to (3)

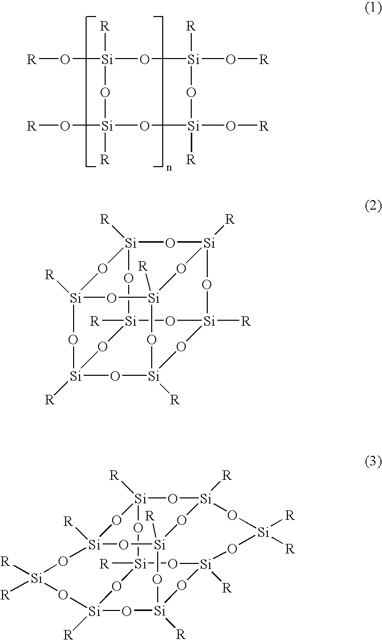

where each R independently represents any one of an alkyl group, alkoxy group, aryl group, and aryl group in which at least one hydrogen atom is replaced by a halogen atom, and in the formula (1), n is an integer from 1 to 3.

In this case, the insulating section with high hygroscopicity can easily be formed.

In the insulator composition according to the first aspect of the invention, the alkyl group is preferably selected from the group consisting of a straight chain alkyl group having a carbon number of 1 to 10, a branched alkyl group having a carbon number of 1 to 10, and a cyclic alkyl group having a carbon number of 4 to 6.

This causes the affinity (compatibility) of the insulator composition with an organic material (particularly with an organic polymer) to become high.

In the insulator composition according to the first aspect of the invention, the alkoxy group is preferably selected from the group consisting of a straight chain alkoxy group having a carbon number of 1 to 10 and a branched alkoxy group having a carbon number of 1 to 10.

This causes the affinity (compatibility) of the insulator composition with an organic material (particularly with an organic polymer) to become high.

In the insulator composition according to the first aspect of the invention, the aryl group is preferably a phenyl group.

This causes the affinity (compatibility) of the insulator composition with an organic material (particularly with an organic polymer) to become high.

In the insulator composition according to the first aspect of the invention, the halogen atom is preferably a fluorine atom.

This causes the affinity (compatibility) of the insulator composition with an organic material (particularly with an organic polymer) to become high.

The insulator composition according to the first aspect of the invention preferably further includes a polymerizable compound.

In this case, the insulator composition can be cured by irradiation with light or heating to form the insulating section. The mechanical strength of the insulating section to be obtained can also be more improved.

In the insulator composition according to the first aspect of the invention, the polymerizable compound is preferably at least one kind of acrylic acid-based compounds, epoxy-based compounds, and oxetane-based compounds.

It is preferable to use these compounds since they have particularly high reactivity.

The insulator composition according to the first aspect of the invention preferably further includes a thermoplastic resin.

In this case, the insulator composition can be fixed (cured) by drying removing a solvent) to form the insulating section. The mechanical strength of the insulating section to be obtained can thus be more improved.

In the insulator composition according to the first aspect of the invention, the content of the polysilsesquioxane derivative is preferably 0.1 to 50% by weight.

Thus, the mechanical strength of the formed insulating section is reliably maintained, and an effect caused by addition of the PSQ derivative, namely, high hygroscopicity is also obtained.

An organic semiconductor device according to a second aspect of the invention includes an insulating section formed by using the insulator composition according to the first aspect of the invention.

Thus, moisture is absorbed in the insulating section so that the degradation and deterioration of the organic semiconductor layer can be prevented. As a result, an organic semiconductor device with high reliability can be obtained.

It is preferable that the organic semiconductor device according to the second aspect of the invention include an organic thin film transistor and the insulating section be at least one of insulating layers that the organic thin film transistor has.

In this case, the organic thin film transistor with excellent transistor characteristics, which is difficult to deteriorate over time, can be obtained.

In the organic semiconductor device according to the second aspect of the invention, the insulating layer is preferably a gate insulating layer.

Thus, improvement in transistor characteristics can be attained.

An electronic device according to a third aspect of the invention includes the organic semiconductor device according to the second aspect of the invention.

Thus, the electronic device with high reliability can be obtained.

An electronic apparatus according to a fourth aspect of the invention includes the electronic device according to the third aspect of the invention.

Thus, the electronic apparatus with high reliability can be obtained.

### BRIEF DESCRIPTION OF THE DRAWINGS

The invention will be described with reference to the accompanying drawings, wherein like numbers refer to like elements.

FIG. 1 is a block diagram that shows a structure of an active matrix device to which an organic semiconductor device according to an embodiment of the invention is applied.

FIGS. 2A and 2B are a longitudinal sectional view and a plan view, respectively, which show a structure of an organic TFT included in the active matrix device shown in FIG. 1.

FIG. 3 is a longitudinal sectional view that shows an embodiment of an electrophoretic display device.

FIG. 4 is a perspective view that shows an embodiment in which an electronic apparatus according to an embodiment of the invention is applied to a piece of electronic paper.

FIGS. 5A and 5B are views that show an embodiment in which the electronic apparatus according to an embodiment of the invention is applied to a display.

### DESCRIPTION OF THE EMBODIMENT

An insulator composition, an organic semiconductor device, an electronic device, and an electronic apparatus according to the invention will now be described in detail based on the preferred embodiment.

The organic semiconductor device according to an embodiment of the invention means a device having an organic semiconductor layer disposed in a portion thereof. Examples of the organic semiconductor device include an active matrix device structured such that a plurality of organic TFTs are formed on a substrate, and an organic electroluminescent (EL) display device having a plurality of organic EL elements formed to be partitioned.

An exemplary case where the organic semiconductor device according to an embodiment of the invention is applied to an active matrix device will be described below.

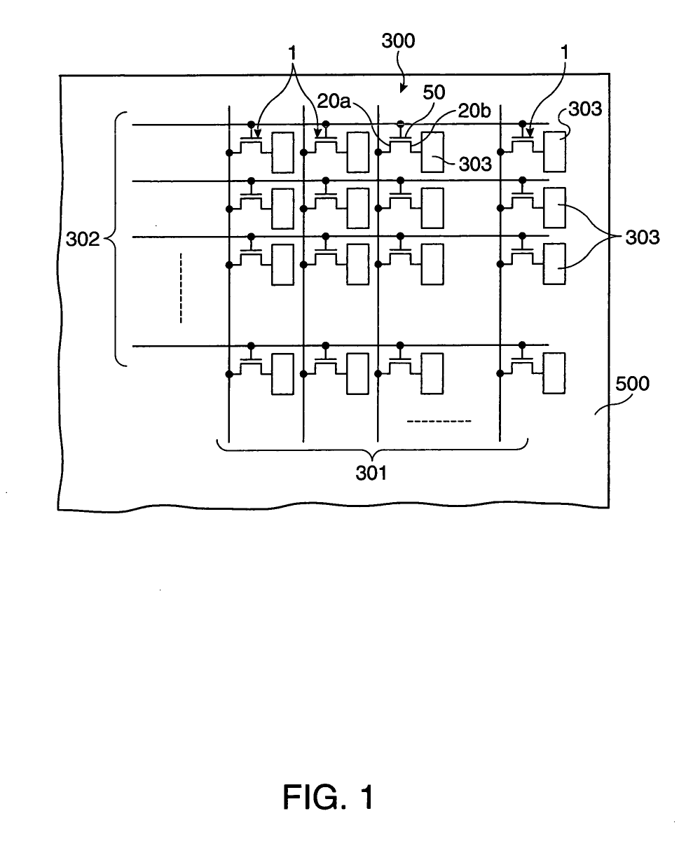

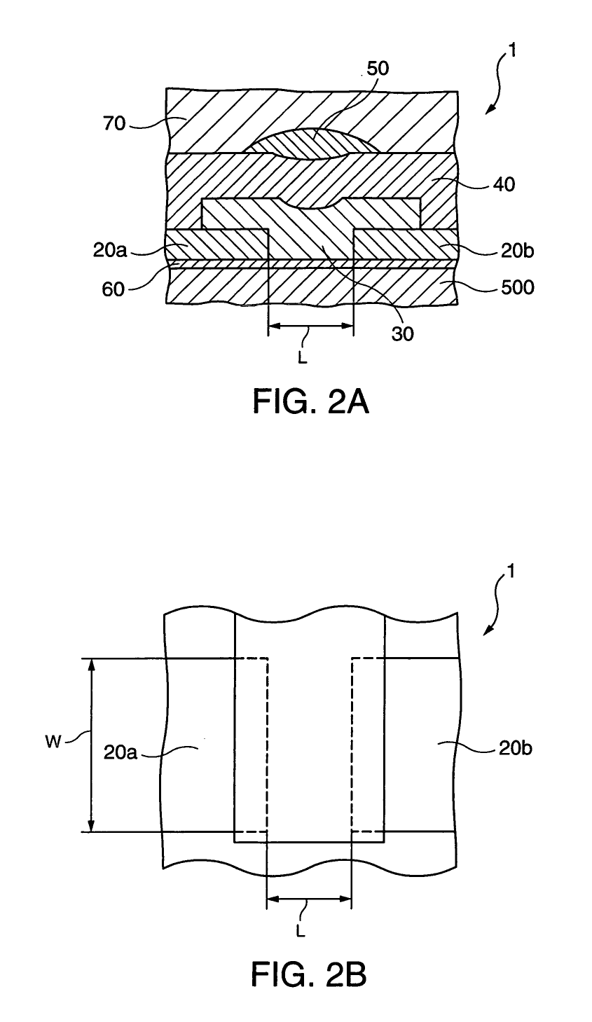

FIG. 1 is a block diagram that shows a structure of an active matrix device to which an organic semiconductor device according to an embodiment of the invention is applied. FIGS. 2A and 2B are a longitudinal sectional view and a plan view, respectively, which show a structure of an organic TFT included in the active matrix device shown in FIG. 1.

An active matrix device 300 shown in FIG. 1 has a substrate 500, a plurality of data lines 301 and a plurality of scanning lines 302, which are orthogonal with each other and both of which are disposed on the substrate 500, organic TFTs 1 (hereinafter, refer to as “TFTs 1”) disposed near the intersections between the data lines 301 and the scanning lines 302, and pixel electrodes (individual electrodes) 303 described later.

The TFT 1 has a gate electrode 50, a source electrode 20a, and a drain electrode 20b, which are connected to the scanning line 302, the data line 301, and the pixel electrode 303, respectively.

As shown in FIG. 2, the TFT 1 of the present embodiment is a top gate type, which has a buffer layer 60 disposed on the substrate 500, a source electrode 20a and a drain electrode 20b that are disposed apart from each other above the buffer layer 60, an organic semiconductor layer 30 that is in contact with the source electrode 20a and the drain electrode 20b, a gate insulating layer 40 positioned between the organic semiconductor layer 30 and the gate electrode 50, and a protective layer 70 disposed so as to cover these layers.

The structures of elements will be sequentially described below.

The substrate 500 supports the layers (elements) constituting the TFT 1 (the active matrix device 300).

For the formation of the substrate 500, glass substrates, plastic substrates (resin substrates) formed of poly(ethylene terephthalate) (PET), poly(ethylene naphthalate) (PEN), polyethersulfone (PES), aromatic polyester (liquid crystal polymer), (polyimide (PI), etc., quartz substrates, silicon substrates, metal substrates, GaAs substrates, and other substrates can be used.

If the TFT 1 is provided with flexibility, a plastic substrate or a thin relatively small film thickness) metal substrate is chosen for the substrate 500.

The buffer layer 60 is provided on the substrate 500.

The buffer layer 60 has a function to prevent the invasion of moisture into the organic semiconductor layer 30 described later. If the substrate 500 is formed of glass or the like, the buffer layer 60 also has a function to prevent the diffusion of ion and the like from the substrate 500 to the organic semiconductor layer 30.

The buffer layer 60 as described above, the gate insulating layer 40 described later, and the protective layer 70 are formed by using an insulator composition according to an embodiment of the invention. Detailed description of the insulator composition will be given later.

The average thickness of the buffer layer 60 is preferably about 1 to 1000 nm, and more preferably about 10 to 700 nm.

The source electrode 20a and the drain electrode 20b are provided apart from each other for a predetermined distance on the buffer layer 60.

As the constituent material for the source electrode 20a and the drain electrode 20b, metallic materials such as Au, Ag, Cu, Pt, Ni, Cr, Ti, Ta, Al, or alloys including these materials can be mentioned. These materials may be used singly or in combination of two or more kinds thereof.

Among these materials, the materials primarily contain Au, Ag, Cu, Pt, or alloys including them are preferred as the constituent materials for the source electrode 20a and the drain electrode 20b. These materials have relatively large work functions. For this reason, if the organic semiconductor layer 30 is p-type as described later, the efficiency of injecting holes (carriers) to the organic semiconductor layer 30 can be improved by forming the source electrode 20a of the preferred material.

The average thicknesses of the source electrode 20a and the drain electrode 20b are not particularly limited, but are preferably about 10 to 2000 nm, and more preferably about 50 to 1000 nm.

The distance between the source electrode 20a and the drain electrode 20b, namely, a channel length L shown in FIGS. 2A and 2B is preferably about 2 to 30 μm, and more preferably about 2 to 20 μm. The channel length L is set in the range mentioned above so that the characteristics of the TFT 1 (particularly an increase in ON current value) can be improved.

The length of the source electrode 20a and the drain electrode 20b, namely, a channel width W shown in FIG. 2B is preferably about 0.1 to 5 mm, and more preferably about 0.3 to 3 mm. The channel width W is set in the range mentioned above, allowing the parasitic capacitance to be reduced and the characteristics of the TFT 1 to be prevented from deteriorating. An increase in size of the TFT 1 can also be prevented.

The organic semiconductor layer 30 is provided to be in contact with the source electrode 20a and the drain electrode 20b.

In the embodiment, the organic semiconductor layer 30 is primarily made of a p-type organic semiconductor material. Either a polymer organic semiconductor material (macromolecule-based organic semiconductor material) or a low-molecular-based organic semiconductor material may be used as the p-type organic semiconductor material.

Examples of the polymer organic semiconductor material include: poly (3-alkylthiophene), poly(3-hexylthiophene) (P3HT), poly(3-octylthiophen), poly(2,5-thienylenevinylene) (PTV), poly(para-phenylenevinylene) (PPV), poly(9,9-dioctylfluorene) (PFO), poly(9,9-dioctylfluorene-co-bis-N,N′-(4-methoxyphenyl)-bis-N,N′-phenyl-1,4-phenylenediamine) (PFMO), poly(9,9-dioctylfluorene-co-benzothiadiazole) (BT), fluorene-triallylamine copolymer, triallylamine-based polymer, and fluorene-bithiophene copolymer (F8T2).

Examples of the low-molecular-based organic semiconductor material include: C60; metal phthalocyanine and substitution derivative thereof, acene molecule materials such as anthracene, tetracene, pentacene, and hexacene; α-oligothiophenes such as quarterthiophene (4T), sexithiophene (6T), octithiophene (8T), dihexylquarterthiophene (DH4T), and dihexylsexithiophene (DH6T).

The average thickness of the organic semiconductor layer 30 is not particularly limited, but is preferably about 0.1 to 1000 nm, more preferably about 1 to 500 nm, and even more preferably about 1 to 100 nm.

The gate insulating layer (insulating layer) 40 is provided so as to cover the organic semiconductor layer 30, the source electrode 20a, and the drain electrode 20b.

The source electrode 20a and the drain electrode 20b are insulated from a gate electrode 50 described later by the gate insulating layer 40.

The average thickness of the gate insulating layer 40 is not particularly limited, but is preferably about 10 to 5000 nm, more preferably about 100 to 2000 nm. By setting the thickness of the gate insulating layer 40 in the range mentioned above, the source electrode 20a and the drain electrode 20b can be reliably insulated from the gate electrode 50 and the operating voltage of the TFT 1 can also be reduced.

In addition, the gate insulating layer 40 is not limited to a single layered one, but may be a multilayered one in which a plurality of layers are stacked.

The gate electrode 50 that applies an electric field to the organic semiconductor layer 30 is provided at a predetermined location on the gate insulating layer 40, namely, at a position corresponding to the region between the source electrode 20a and the drain electrode 20b.

A constituent material of the gate electrode 50 is not particularly limited as long as it is a known electrode material. Specifically, metallic materials such as Cr, Al, Ta, Mo, Nb, Cu, Ag, Au, Pd, In, Ni Nd, Co, and alloys containing these materials; and oxides thereof and the like may be used.

The gate electrode 50 may be made of a conductive organic material.

The average thickness of the gate electrode 50 is not particularly limited, but is preferably about 0.1 to 2000 nm, and more preferably about 1 to 1000 nm.

The protective layer 70 is provided so as to cover the layers described above.

The protective layer 70 has a function to prevent the invasion of moisture into the organic semiconductor layer 30 and a function to prevent the contact of the gate electrode 50 with a foreign substance that causes a short circuit between the TFTs 1 adjacent with each other.

The average thickness of the protective layer 70 is not particularly limited, but is preferably about 0.01 to 10 μm, and more preferably about 0.1 to 5 μm.

In the TFT 1 as described above, if a gate voltage is applied to the gate electrode 50 with a voltage applied between the source electrode 20a and the drain electrode 20b, a channel is formed in a region of the organic semiconductor layer 30 near the interface of it and the gate insulating layer 40, and a current flows between the source electrode 20a and the drain electrode 20b as carriers (holes) move in the channel region.

Namely, in the OFF state in which a voltage is not applied to the gate electrode 50, even if a voltage is applied between the source electrode 20a and the drain electrode 20b, only a minute current flows because very few carriers exist in the organic semiconductor layer 30.

In the ON state in which a voltage is applied to the gate electrode 50, electric charges are induced in an area of the organic semiconductor layer 30 that faces the gate insulating layer 40 to form a channel flow path of carriers). When a voltage is applied between the source electrode 20a and the drain electrode 20b in this state, a current flows through the channel region.

In addition, the TFT 1 is not limited to a top gate type TFT, but may be a bottom gate type TFT.

Insulating layers (insulating sections) such as the gate insulating layer 40, buffer layer 60, and protective layer 70 described above are formed by using insulator compositions according to an embodiment of the invention.

An insulator composition according to an embodiment of the invention will be described below.

The insulator composition contains a polysilsesquioxane (hereinafter abbreviated as “PSQ”) derivative having an organic group as a substituent.

PSQ, a collective term of polysiloxane with SiO_{3/2} bond in the framework, is typically obtained by hydrolyzing and condensing a trifunctional silicon compound.

PSQ used for the invention can be purchased from, for example, Hybrid Plastics, Inc., and can also be readily manufactured by appropriately combining general organic chemical methods disclosed in, Houben-Wyle, Methods of Organic Chemistry, Georg Thieme Verlag, Stuttgart; Organic Syntheses, John Wiley & Sons, Inc.; Organic Reactions, John Wiley & Sons Inc.; Comprehensive Organic Synthesis, Pergamon Press; Shinjikkenkagakukouza, Maruzen; etc.

The PSQ derivative has extremely high hygroscopicity because of its Si—O structure, and also has high affinity with an organic material (organic polymer) because of having an organic group as a substituent.

Therefore, at least one of the gate insulating layer 40, buffer layer 60, and protective layer 70 mentioned above is formed by using an insulator composition that contains the PSQ derivative, so that the formed layer has high hygroscopicity. Moisture is absorbed by the layer, and therefore can be prevented from invading the organic semiconductor layer 30. The organic semiconductor layer 30 can thus be prevented from being degraded and deteriorating over time. As a result, characteristics of the TFT 1 can be prevented from deteriorating over time.

The PSQ derivative has high affinity with an organic material (particularly with an organic polymer). Therefore, if the gate insulating layer 40 is formed by using an insulator composition of the invention, a high degree of adhesion between the gate insulating layer 40 and the organic semiconductor layer 30 can be obtained. As a result, improvement in characteristics of the TFT 1 can be achieved. In other words, an insulator composition according to an embodiment of the invention is preferable particularly for forming the gate insulating layer 40 among insulating layers included in the TFT 1.

Since the PSQ derivative has high affinity with an organic polymer, the use of an insulator composition according to an embodiment of the invention as a liquid material containing an organic solvent allows the layers mentioned above to be formed by a liquid phase process. This can reduce manufacturing time and cost of the layers, leading to the reduction of manufacturing time and cost of the TFT (organic semiconductor device) 1. Furthermore, proper choice of the type of organic solvent enables forming the gate insulating layer 40 while preventing the degradation and deterioration of the organic semiconductor layer 30 during the formation of the gate insulating layer 40.

As preferable examples of the PSQ derivative, compounds represented by the following formulas (1) to (3) can be mentioned.

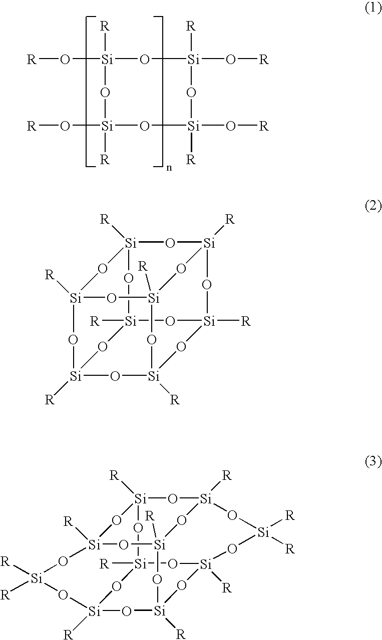

(In the formulas (1) to (3), each R independently represents any one of an alkyl group, alkoxy group, aryl group, and aryl group in which at least one hydrogen atom is replaced by a halogen atom. In the formula (1), n is an integer from 1 to 3.)

As the alkyl group, an alkyl group having a carbon number of 1 to 15 is preferable, and a straight chain or branched alkyl group having a carbon number of 1 to 10 or a cyclic alkyl group having a carbon number of 4 to 6 is more preferable.

As the alkoxy group, an alkoxy group having a carbon number of 1 to 15 is preferable, and a straight chain or branched alkoxy group having a carbon number of 1 to 10 is more preferable.

As the aryl group, an aryl group having from one to three cyclic structures such as, for example, a phenyl group, naphthyl group, biphenyl group, anthranyl group, or terphenyl group is preferable, and an aryl group having a phenyl group is more preferable.

The halogen atom may be any one of fluorine atom, chlorine atom, bromine atom, and the like, and is preferably a fluorine atom.

Specific examples of R described above include: a methyl group, ethyl group, propyl group, isopropyl group, butyl group, 2-methylpropyl group, t-butyl group, pentyl group, isopentyl group, hexyl group, methoxy group, ethoxy group, propoxy group, butoxy group, pentoxy group, cyclopentyl group, cyclohexyl group, phenyl group, and substituted phenyl group indicated below.

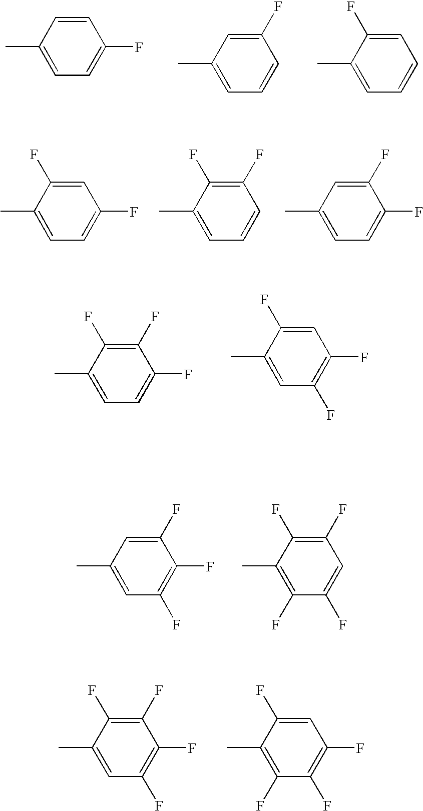

Compounds indicated in the formulas (1) to (3) that have these substituents as R have high affinity (compatibility) with organic materials (particularly with organic polymers).

The PSQ derivative may contain at least one type of the compounds represented by the formulas (1) to (3), and preferably contains the compounds represented by formulas (2) and (3) as the main component. The compounds represented by formulas (2) and (3) are excellent in hygroscopicity.

The content (the percentage of the weight of the PSQ derivative in the total weight of the insulator composition) of the PSQ derivative as described above may be preferably about 0.1 to 50 wt %, more preferably about 1 to 50 wt %, and even more preferably about 10 to 50 wt %. Thus, the mechanical strength of the formed insulating layer (insulating section) is reliably maintained, and an effect caused by addition of the PSQ derivative, namely, high hygroscopicity is also obtained.

Other components to be added to the insulator composition according to an embodiment of the invention include, for example, organic solvents, polymerizable compounds, thermoplastic resins, inorganic filler, coupling agents, amine compounds, polymerization initiators, polymerization accelerators; these components can be used singly or in combination of two or more kinds thereof.

For example, the insulator composition according to an embodiment of the invention can be prepared by solving the PSQ derivative in an organic solvent.

In this case, the insulator composition can be fixed by drying removing the solvent) to form the insulating layer (insulating section).

The insulator composition according to an embodiment of the invention can be prepared by solving the PSQ derivative and a polymerizable compound in an organic solvent.

In this case, the insulator composition can be cured by irradiation with light or heating after dried removal of the solvent) to form the insulating layer (insulating section).

The mechanical strength of the insulating layer (insulating section) to be obtained can thus be improved.

As the polymerizable compound, acrylic acid-based compounds, epoxy-based compounds, oxetane-based compounds, styrene-based compounds, polyimide precursors, and polyurethane precursors, for example, can be mentioned. It is preferable to use as the polymerizable compound at least one kind of acrylic acid-based compounds, epoxy-based compounds, and oxetane-based compounds since these compounds have particularly high reactivity.

Examples of the acrylic acid-based compound include: aromatic (meth)acrylate compounds such as bisphenol A (meth)acrylate, bisphenol F (meth)acrylate, phenol novolac (meth)acrylate, cresol novolac (meth)acrylate, trisphenolmethane(meth)acrylate, bisphenol S (meth)acrylate, and bisphenol (meth)acrylate; and aliphatic (meth)acrylate compounds such as ethylene glycol di(meth)acrylate, propylene glycol di(meth)acrylate, neopentyl glycol di(meth)acrylate, trimethylolpropanetri(meth)acrylate, and glycerin (meth)acrylate.

Examples of the epoxy-based compound include: aromatic epoxide compounds such as bisphenol A epoxide, bisphenol F epoxide, phenol novolac epoxide, cresol novolac epoxide, trisphenolmethane epoxide, bisphenol S epoxide, and bisphenol epoxide; glycidyl ether compounds such as ethylene glycol diglycidyl ether, propyleneglycol diglycidyl ether, neopentylglycol diglycidyl ether, trimethylolpropanetriglycidyl ether, and glycerin diglycidyl ether; and bis(2,3-epoxy cyclopentyl)ether, bis(2,3-epoxy cyclohexylmethyl)adipate, bis(2,3-epoxy-6-methylcyclohexylmethyl)adipate, 3,4-epoxy cyclohexylmethyl 3,4-epoxy cyclohexane carboxylate, 3,4-epoxy-6-methylcyclohexylmethyl 3,4-epoxy-6-methyl cyclohexane carboxylate, dicyclopentadiene oxide, vinyl cyclohexane oxide, and the alicyclic epoxy compounds indicated below.

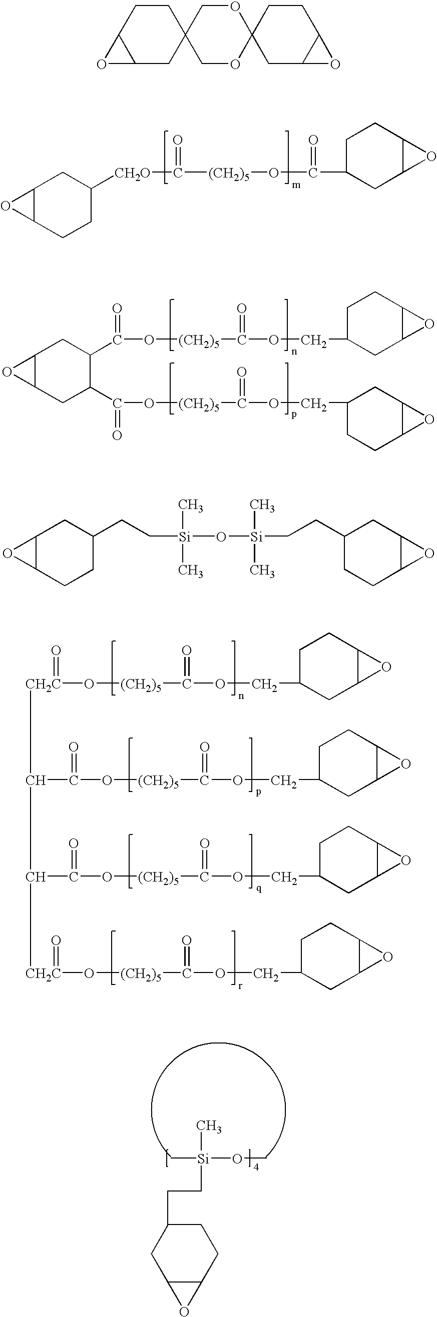

(In these formulas, m is an integer equal to or more than 1, and n, p, q, and r are each independent integers equal to or greater than 0.)

Examples of the oxetane-based compound include, oxetane compounds indicated below and the like.

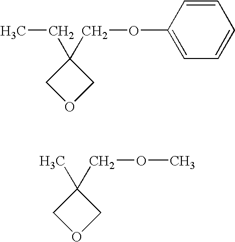

In this case, it is preferable to add a polymerization initiator (particularly photo-polymerization initiator).

As the polymerization initiator, for example, acetophenone, benzophenone, benzoin ether, thioxanthone, camphorquinone, (2,4,6-trimethylbenzoyl)diphenylphosphine oxide, ketals, dibenzoyls, onium sale, and nucleophilic substituents of these compounds can be mentioned; at least one of these compounds can be selected for use.

As preferable examples of the polymerization initiator, for example, 2-hydroxy-2-methyl-1-phenylpropane-1-one, 1-hydroxycyclohexylphenylketone, 1-(4-isopropylphenyl)-2-hydroxy-2-methylpropane-1-one, benzyldimethylketal α,α-dimethoxy-α-morpholino-methylthiophenylacetophenone, aromatic sulfonium salt, aromatic iodonium salt, and a mixture of 2,4-diethylxanthone and p-dimethylaminobenzoic acid methyl can be mentioned.

The insulator composition according to an embodiment of the invention can be prepared by solving the PSQ derivative and a thermoplastic resin in an organic solvent.

In this case, the insulator composition can be fixed (cured) by drying removing the solvent) to form the insulating layer (insulating section).

The mechanical strength of the insulating layer (insulating section) to be obtained can thus be improved.

Examples of the thermoplastic resin include: polyethylene, polypropylene, polyolefin such as ethylene-vinyl acetate copolymer, modified polyolefin, polyamide (e.g., nylon-6, nylon-46, nylon-66, nylon-610, nylon-612, nylon-11, nylon-12, nylon-6/12, and nylon-6/66), thermoplastic polyimide, liquid crystal polymer such as aromatic polyester, polyphenylene oxide, polyphenylene sulfide, polycarbonate, polymethyl methacrylate, polyether, polyetheretherketone, polyetherimido, and polyacetal; and styrene-based, styrene-based, poly(vinyl chloride)-based, polyurethane-based, polyester-based, polyamide-based, polybutadiene-based, transpolyisoprene-based, fluorocarbon rubber-based, chlorinated polyethylene-based, and other various types of thermoplastic elastomers. These resins may be used singly or in combination of two or more kinds thereof.

As the usable solvent, inorganic solvents such as nitric acid, sulfuric acid, ammonia solution, hydrogen peroxide, water, carbon disulfide, carbon tetrachloride, and ethylene carbonate can be mentioned. Various types of organic solvents can also be used. Examples of the organic solvents include: ketone-based solvents such as methyl ethyl ketone (MEK), acetone, diethyl ketone, methyl isobutyl ketone (MIBK), methyl isopropyl ketone (MIPK), and cyclohexanone; alcohol-based solvents such as methanol ethanol, isopropanol, ethylene glycol diethylene glycol (DEG), and glycerin; ether-based solvents such as diethyl ether, diisopropyl ether, 1,2-dimethoxyethane (DME), 1,4-dioxane, tetrahydrofuran (THF), tetrahydropyran (THP), anisole, diethylene glycol dimethylether (diglyme), and diethylene glycol ethylether (carbitol); cellosolve-based solvents such as methyl cellosolve, ether cellosolve, and phenyl cellosolve; aliphatic hydrocarbon-based solvents such as hexane, pentane, heptane, and cyclohexane; aromatic hydrocarbon-based solvents such as toluene, xylene, benzene, trimethylbenzene, and tetramethylbenzene; aromatic heterocyclic compound-based solvents such as pyridine, pyrazine, furan, pyrrole, thiophene, methylpyrrolidone; amide-based solvents such as N,N-dimethylformamide (DMF), and N,N-dimethylacetamide (DMA); halide-based solvents such as dichloromethane, chloroform, and 1,2-dichloroethane; esther-based solvents such as ethyl acetate, methyl acetate, and ethyl formate; and sulfur compound-based solvents such as dimethyl sulfoxide (DMSO), and sulfolane; nitrile-based solvents such as acetonitrile, propionitrile, and acrylonitrile; organic acid-based solvents such as formic acid, acetic acid, and trichloroacetic acid. Alternatively, mixed solvents containing these solvents can be used.

Electronic Device

An exemplary electrophoretic display device into which an active matrix device as described above is incorporated will now be described as an electronic device according to an embodiment of the invention.

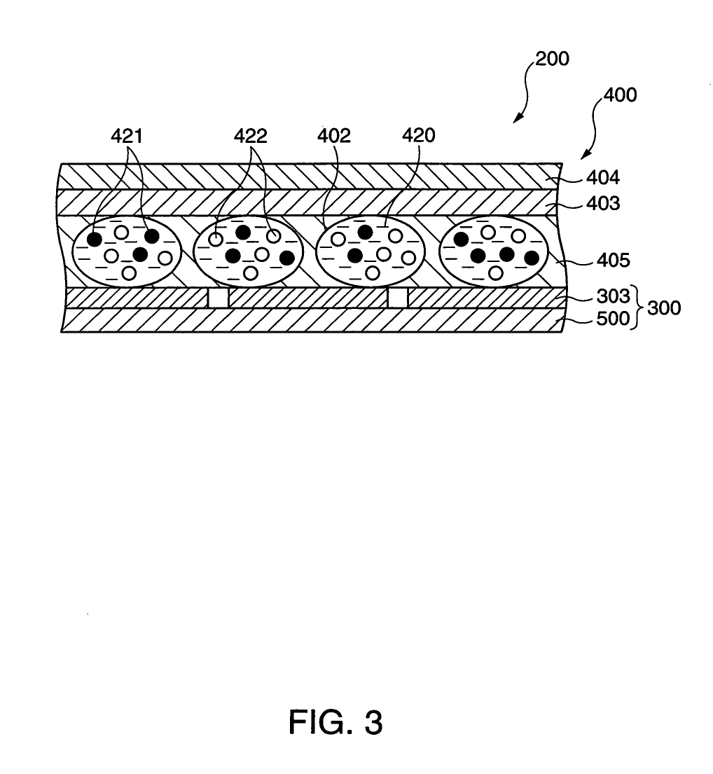

FIG. 3 is a longitudinal sectional view that shows an embodiment of the electrophoretic display device.

An electrophoretic display device 200 shown in FIG. 3 includes the active matrix device 300 described above and an electrophoretic display section 400 that is provided on the active matrix device 300.

The electrophoretic display section 400 includes a transparent board 404 with a transparent electrode (common electrode) 403 and microcapsules 402 fixed to a transparent electrode 403 by a binder member 405.

The active matrix device 300 and the electrophoretic display section 400 are joined such that the microcapsules 402 are in contact with the pixel electrode 303.

An electrophoretic dispersion liquid 420 containing a plurality of types of electrophoretic particles with different characteristics, two types of electrophoretic particles 421 and 422 with different charge and color (hue) in this embodiment, is sealed in each capsule 402.

In the electrophoretic display device 200 structured in this manner, when one or plural scanning lines 302 are supplied with a selection signal (selection voltage), the TFT 1 that is connected to the scanning line 302 supplied with the selection signal (selection voltage) turns on.

By the turn-on of the TFT 1, the data line 301 and the pixel electrode 303 that are connected to the TFT 1 are made substantially conductive. At this time, if a data line 301a has been supplied with desired data (voltage), the data (voltage) is supplied to the pixel electrode 303.

As a result, an electric field is created between the pixel electrode 303 and the transparent electrode 403. In accordance with the direction and strength of the electric field and characteristics of the electrophoretic particles 421 and 422, the electrophoretic particles 421 and 422 migrate by electrophoresis towards either of the electrodes.

When the supply of the selection signal (selection voltage) to the scanning line 302 is stopped in this state, the TFT 1 turns off. The data line 301 and the pixel electrode 303 that are connected to the TFT 1 are made non-conductive.

Thus, a desired image (information) can be displayed on the display surface side (the side of the transparent board 404) of the electrophoretic display device 200 by appropriately combining the supply and its stoppage of the selection signal to the scanning line 302 as well as the supply and its stoppage of the data to the data line 301.

Particularly in the electrophoretic display device 200 of the embodiment, a multiple tone image can be displayed because the electrophoretic particles 421 and 422 have different colors.

The electrophoretic display device 200 of the embodiment has the active matrix device 300, enabling the TFT 1 connected to the particular scanning line 302 to selectively turn on or off. This makes it difficult to cause a cross talk problem, and makes it possible to speed up circuit operations. Images (information) of high quality can thereby be obtained.

The electrophoretic display device 200 of the embodiment operates with a low drive voltage, allowing the power to be saved.

In addition, the display device into which an active matrix device with the TFT 1 as described above is incorporated is not limited to the application to the electrophoretic display device 200 described above, but can be applied, for example, to a liquid crystal display device and the like.

Electronic Apparatus

The electrophoretic display device 200 as described above can be incorporated into various electronic apparatuses. An electronic apparatus according to an embodiment of the invention with the electrophoretic display device 200 will be described below.

Electronic Paper

An embodiment in which an electronic apparatus according to an embodiment of the invention is applied to a piece of electronic paper will initially be described.

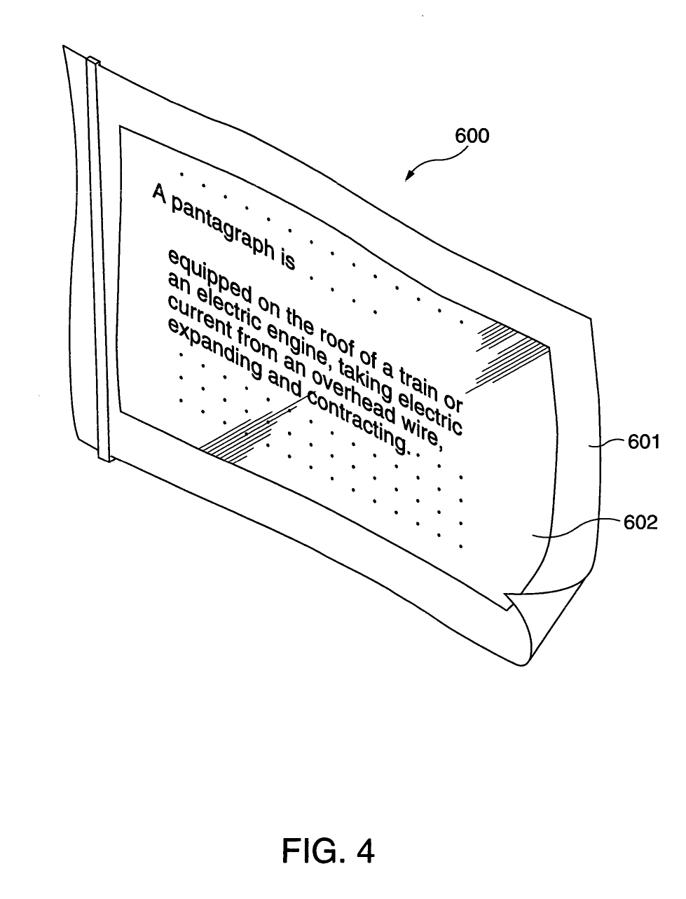

FIG. 4 is a perspective view that shows the embodiment in which an electronic apparatus according to an embodiment of the invention is applied to a piece of electronic paper.

A piece of electronic paper 600 shown in the drawing includes a main body 601 composed of a rewritable sheet having the same texture and flexibility as paper and a display unit 602.

In this electronic paper 600, the display unit 602 is made of the above electrophoretic display device 200.

Display

An embodiment in which the electronic apparatus of the invention is applied to a display will next be described.

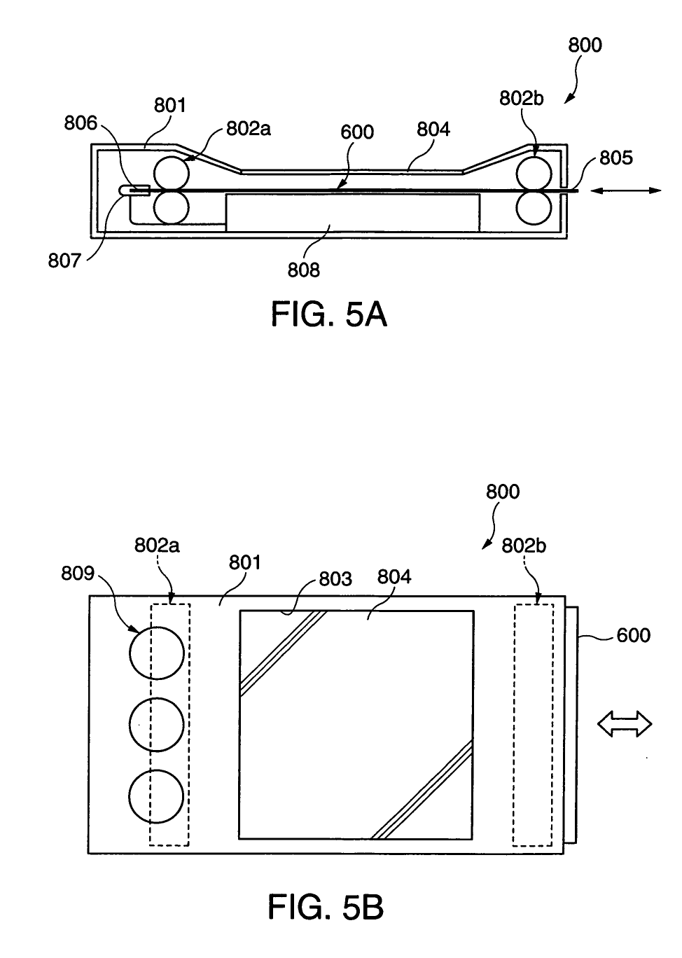

FIGS. 5A and 5B are views that show an embodiment in which the electronic apparatus according to an embodiment of the invention is applied to a display; FIG. 5A is a sectional view and FIG. 5B is a plan view.

A display 800 shown in these drawings includes a main body 801 and the electronic paper 600 provided to be freely attachable to or detachable from the main body 801. The electronic paper 600 has the above structure, namely, the same structure as shown in FIG. 4.

The main body 801 has in the side portion (right side in the drawing) an insertion opening 805 into which the electronic paper 600 can be inserted, and has two pairs of carrier rollers 802a and 802b provided in the inside. When inserted through the insertion opening 805 into the inside of the main body 801, the electronic paper 600 is placed in the main body 801 to be sandwiched by the pair of carrier rollers 802a and 802b.

A rectangular hole section 803 is formed at the display surface side of the main body 801 (as shown in FIG. 5B, at the front side of the page), and a transparent glass plate 804 is fitted to the hole section 803. Thus, the electronic paper 600 placed in the main body 801 is visible from the outside of the main body 801. Namely, in this display 800, the display surface is structured such that the electronic paper 600 placed in the main body 801 is recognized with eyes through the transparent glass plate 804.

A terminal section 806 is provided at the end in the insertion direction (at the left side in the drawing) of the electronic paper 600. Inside the main body 801, a socket 807 is provided. With the electronic paper 600 placed in the main body 801, the terminal section 806 is connected to the socket 807. A controller 808 and an operation section 809 are electrically connected to the socket 807.

In this display 800, the electronic paper 600 is placed to be freely attachable to or detachable from the main body 801, and therefore can also be used portably in the state of being detached from the main body 801.

In this display 800, the electronic paper 600 is made of the electrophoretic display device 200 as described above.

The electronic apparatus according to an embodiment of the invention is not limited to the application to those described above. The application to various types apparatuses can be made. Examples of the apparatuses include: television sets, viewfinder type or monitor-direct-view-type video tape recorders, car navigation devices, pagers, personal organizers, electronic calculators, electronic paper, word processors, personal computers, work stations, television telephones, POS terminals, and apparatuses with a touch panel. The electrophoretic display device 200 can be applied to displays of these various electronic apparatuses.

The insulator composition, organic semiconductor device, electronic device, and electronic apparatus according to an embodiment of the invention have been described based on the embodiments with reference to the accompanying drawings. However, the invention is not limited to these embodiments.

Although the case in which an organic semiconductor device is applied to an active matrix device is described as an example, an organic semiconductor device of the invention may also be applied to an organic EL display device.

In this case, for example, a bank for partitioning pixels (organic EL elements), a protective film, and the like can be formed by using an insulator composition according to an embodiment of the invention.

### EXAMPLE

Specific examples of the invention will be described in the following.

1. Preparation of the Insulator Composition

Initially, components shown in the following are mixed to prepare insulator compositions A to F

Insulator Composition A (the Invention)

| | |
|---|---|
| PSQ derivative | |
| Compound represented by the formula (1) | 40 wt % |
| (all Rs represent propyl group) | |
| Polymerizable compound | |
| Bisphenol A acrylate | 40 wt % |
| Polymerization initiator | |
| 1-hydroxycyclohexylphenylketone | 1 wt % |
| Organic solvent | |
| Diethylene glycol ethylether | 19 wt % |

Insulator Composition B (the Invention)

| | |
|---|---|
| PSQ derivative | |
| Compound represented by the formula (2) | 40 wt % |
| (all Rs represent ethoxy group) | |
| Polymerizable compound | |
| Propyleneglycol diglycidyl ether | 40 wt % |
| Polymerization initiator | |
| 1-hydroxycyclohexylphenylketone | 1 wt % |
| Organic solvent | |
| Diethylene glycol ethylether | 19 wt % |

Insulator Composition C (the Invention)

| | |
|---|---|
| PSQ derivative | |
| Compound represented by the formula (3) | 40 wt % |
| (all Rs represent phenyl group) | |
| Polymerizable compound | |
| Propyleneglycol diglycidyl ether | 40 wt % |
| Polymerization initiator | |
| 1-hydroxycyclohexylphenylketone | 1 wt % |
| Organic solvent | |
| Diethylene glycol ethylether | 19 wt % |

Insulator Composition D (the Invention)

| PSQ derivative | |
|---|---|
| Compound represented by the formula (1) | 30 wt % |
| (all Rs represent phenyl group) | |
| Compound represented by the formula (3) | 10 wt % |
| (all Rs represent ethyl group) | |
| Polymerizable compound | |
| Bisphenol A acrylate | 40 wt % |
| Polymerization initiator | |
| 1-hydroxycyclohexylphenylketone | 1 wt % |
| Organic solvent | |
| Diethylene glycol ethylether | 19 wt % |

Insulator Composition E (the Invention)

| PSQ derivative | |
|---|---|
| Compound represented by the formula (3) | 40 wt % |
| (all Rs represent 2-fluoro-phenyl group) | |
| Thermoplastic resin | |
| Polypropylene | 40 wt % |
| Organic solvent | |
| Diethylene glycol ethylether | 20 wt % |
| Insulator Composition F (Comparative Example) | |
| Polymerizable compound | |
| Bisphenol A acrylate | 80 wt % |
| Polymerization initiator | |
| 1-hydroxycyclohexylphenylketone | 1 wt % |
| Organic solvent | |
| Diethylene glycol ethylether | 19 wt % |

2. Fabrication of Organic TFT

As described below, 200 TFTs were fabricated on a glass substrate in each example.

### Example 1

[1] A glass substrate (manufactured by NEC Corning Inc., “0A10”) was prepared, cleaned by using water, and thereafter dried.

[2] A 5% wt/vol solution of polymethyl methacrylate (PMMA) in butyl acetate was applied by a spin coating method (2400 rpm), and thereafter dried at 60° C. for 10 minutes.

Thus, a buffer layer having an average thickness of 500 nm was formed.

[3] A resist layer was formed on the buffer layer in an area other than the area for forming a source electrode and a drain electrode.

A gold thin film was formed on the buffer layer that was exposed from the resist layer by a vapor deposition method, and thereafter the resist layer was removed.

As a result, the source electrode and the drain electrode both having an average thickness of 100 nm were formed.

The distance between the source electrode and the drain electrode (channel length L) was 20 μm and the channel width W was 1 mm.

[4] A 1% wt/vol solution of fluorene-bithiophene copolymer (F8T2) in toluene was applied by a spin coating method (2400 rpm), and thereafter was dried at 60° C. for 10 minutes.

Thus, an organic semiconductor layer having an average thickness of 50 nm was formed.

[5] The insulator composition A was applied to cover the source electrode, the drain electrode, and the organic semiconductor layer by a spin coating method (2400 rpm).

Thereafter, the formed liquid coat was dried at 60° C. for 10 minutes, and then was irradiated with UV radiation having an intensity of 7 mW/cm₂ for 120 seconds to cure the insulator composition.

Thus, a gate insulating layer having an average thickness of 500 nm was formed.

[6] A water dispersion of Ag particles was applied to a region on the gate insulating layer corresponding to the region between the source electrode and the drain electrode by an ink-jet method, and then was dried at 80° C. for 10 minutes.

Thus, a gate electrode having an average thickness of 100 nm and an average width of 30 μm.

[7] A 2% wt/vol solution of polyvinyl phenol (PVP) in butanol was applied by a spin coating method (2400 rpm), and thereafter was dried at 60° C. for 10 minutes.

Thus, a protective layer having an average thickness of 500 nm was formed.

### Example 2

A TFT was fabricated in the same manner as in Example 1, with the exception of using the insulator composition B in the process [5] described above.

### Example 3

A TFT was fabricated in the same manner as in Example 1, with the exception of using the insulator composition C in the process [5] described above.

### Example 4

A TFT was fabricated in the same manner as in Example 1, with the exception of using the insulator composition D in the process [5] described above.

### Example 5

A TFT was fabricated in the same manner as in Example 1, with the exception of using the insulator composition E and omitting the irradiation of UV in the process [5] described above.

### Comparative Example 1

A TFT was fabricated in the same manner as in Example 1, with the exception of using the insulator composition F in the process [5] described above.

### Comparative Example 2

A TFT was fabricated in the same manner as in Example 1, with the exception of deposition of alumina by a vacuum vapor deposition method to form the gate insulating layer in the process [5] described above.

3. Evaluation

A humidity test was carried out on TFTs fabricated in examples and comparative examples.

In the humidity test, the TFT were left under conditions of 120° C., 100% RH, and 0.2 MPa for 500 hours, and then their changes in transistor characteristics between before and after this operation were checked.

In addition, the transistor characteristics were measured using a commercial measuring device by a conventionally known method.

As a result, some decreases in transistor characteristics (threshold voltage value and S value) were observed in some of the TFTs fabricated in the examples.

In the TFTs in Examples 2, 3, 4, and 5 that use as the PSQ derivatives the compounds represented by the formulas (2) and (3), there is a tendency not to have decreases in transistor characteristics. The tendency is particularly remarkable in Examples 2, 3, and 5 in which the PSQ derivative contains as the main component the compounds represented by the formulas (2) and (3).

In contrast, regarding the TFTs fabricated in Comparative Example 1, decreases in transistor characteristics were observed in many of them.

The TFT of Comparative Example 2 have smaller decreases in transistor characteristics than the TFTs of Comparative Example 1, but initial transistor characteristics were not sufficient. This seems the result to suggest that damage might be caused to an organic semiconductor layer during the formation of the gate insulating layer.

What is claimed is:

1. An insulator composition, comprising a polysilsesquioxane derivative with an organic group as a substituent,
the insulator composition being used for formation of an insulating section that an organic semiconductor device includes.

2. The insulator composition of claim 1, wherein the polysilsesquioxane derivative is at least one kind of compounds represented by formulas (1) to (3) 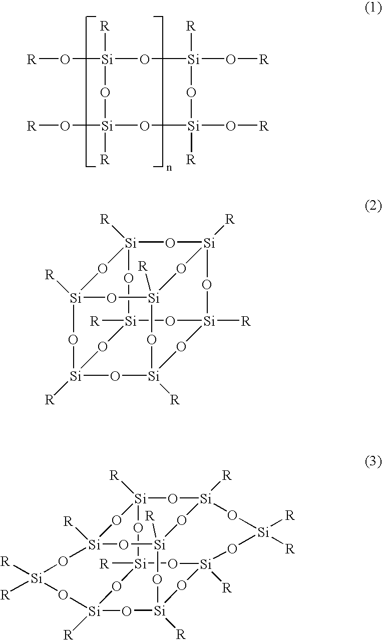
where each R independently represents any one of an alkyl group, alkoxy group, aryl group, and aryl group in which at least one hydrogen atom is replaced by a halogen atom, and in the formula (1), n is an integer from 1 to 3.

3. The insulator composition of claim 2, wherein the alkyl group is selected from the group consisting of a straight chain alkyl group having a carbon number of 1 to 10, a branched alkyl group having a carbon number of 1 to 10, and a cyclic alkyl group having a carbon number of 4 to 6.

4. The insulator composition of claim 2, wherein the alkoxy group is selected from the group consisting of a straight chain alkoxy group having a carbon number of 1 to 10 and a branched alkoxy group having a carbon number of 1 to 10.

5. The insulator composition of claim 2, wherein the aryl group is a phenyl group.

6. The insulator composition of claim 2, wherein the halogen atom is a fluorine atom.

7. The insulator composition of claim 1, further comprising a polymerizable compound.

8. The insulator composition of claim 7, wherein the polymerizable compound is at least one kind of acrylic acid-based compounds, epoxy-based compounds, and oxetane-based compounds.

9. The insulator composition of claim 1, further comprising a thermoplastic resin.

10. The insulator composition of claim 1, wherein the content of the polysilsesquioxane derivative is 0.1 to 50% by weight.

11. An organic semiconductor device, comprising an insulating section formed by using the insulator composition of claim 1.

12. The organic semiconductor device of claim 11, comprising an organic thin film transistor;
wherein the insulating section is at least one of insulating layers that the organic thin film transistor has.

13. The organic semiconductor device of claim 12, wherein the insulating layer is a gate insulating layer.

14. An electronic device, comprising the organic semiconductor device of claim 11.

15. An electronic apparatus, comprising the electronic device of claim 14.
